(19) United States
(12) Patent Application Publication
(10) Pub. No.: US 2024/0324167 A1
(43) Pub. Date: Sep. 26, 2024

(54) ARCHITECTURES AND METHODS FOR COMPUTATION IN MEMORY (CIM) WITH BACKSIDE MEMORY USING HIGH PERFORMANCE (HP) THIN FILM TRANSISTOR (TFT) MATERIAL

(71) Applicant: Intel Corporation, Santa Clara, CA (US)

(72) Inventors: Sudipto Naskar, Portland, OR (US); Abhishek Anil Sharma, Portland, OR (US); Sukru Yemenicioglu, Portland, OR (US); Weimin Han, Portland, OR (US); Van Le, Beaverton, OR (US)

(73) Assignee: Intel Corporation, Santa Clara, CA (US)

(21) Appl. No.: 18/189,808

(22) Filed: Mar. 24, 2023

(51) Int. Cl. H10B 12/00

(52) U.S. Cl. CPC H10B 12/00

(57) ABSTRACT

A high performance (HP) thin film transistor (TFT) architecture to enable fabricating backside memory after metallization starts, or as part of back end of line (BEOL) processes. The HP TFT material is suitable for fabricating the memory stack at the lower BEOL temperatures while still delivering the switching speed requirements of a 3D memory stack in the CIM component. A through silicon via (TSV) architecture connects the logic and the memory in the die.

### BACKGROUND

To increase communication performance between logic and memory in various Von Neumann (or Princeton) styles of architectures, switching speeds can be increased. However, eventually, the distance between the logic and the memory becomes a limiting technical problem that increasing the switching speed cannot overcome. Accordingly, architectures and methodologies that bring memory closer to logic are desirable.

### BRIEF DESCRIPTION OF THE DRAWINGS

FIG. 1 is a simplified cross-sectional image of some of the fabrication layers in a wafer. for introduction of concepts.

FIGS. 2-5 are simplified cross-sectional views of embodiments in various stages of fabrication, in accordance with various embodiments.

FIG. 6 is a revisit of FIG. 1, with additional detail for discussing an exemplary memory cell in the BEOL layers, in accordance with various embodiments.

FIG. 7 illustrates a variation in fabrication, in accordance with various embodiments.

FIG. 8 is an exemplary process flow for fabrication of embodiments defined herein.

FIG. 9 is a top view of a wafer and dies that may embody integrated circuit components, in accordance with any of the embodiments disclosed herein.

FIG. 10 is a simplified cross-sectional side view showing an implementation of an integrated circuit component on a die that may be included in any of the embodiments disclosed herein.

FIG. 11 is a cross-sectional side view of a microelectronic assembly that may include any of the embodiments disclosed herein.

FIG. 12 is a block diagram of an example electrical device that may include any of the embodiments disclosed herein.

### DETAILED DESCRIPTION

Increasing switching speeds has been a focus to improve communication performance between logic and memory in various Von Neumann (or Princeton) styles of architectures for several generations of products. However, the physical distance between the logic and the memory is a limiting technical problem that cannot be improved upon by increasing the switching speed. In some scenarios, the distance between a memory component and a logic component can be in a range of a few millimeters (mm) to a centimeter (cm) or more. Accordingly, many stakeholders are exploring architectures and methodologies to bring memory closer to logic.

One proposed solution, sometimes referred to as “2.5D,” or two-and-a-half-dimensional, places an interposer component in between a logic component and a memory component. However, 2.5D assemblies often have a height that is undesirably large for an intended product. Another solution, often referred to as “3D,” or three-dimensional, attaches a memory die directly to a logic die. However, this approach still relies on two separate die fabrication processes. The demand for continued miniaturization without sacrificing switching speed drive ongoing research in this area.

Embodiments provide a technical solution to this technical problem and other related enhancements, in the form of architectures and methods for computation in memory (CIM) with backside memory using high performance (HP) thin film transistor (TFT) channel material. While Thin Film Transistors (TFTs) generally refer to a variety of available technologies and materials that fabricate a field effect transistor (FET) that is thin with respect to a plane of a device that it is situated in, embodiments advantageously implement the above-mentioned HP TFT channel material in the TFTs. Embodiments advantageously move memory stacks directly into the die that has the logic, enabling CIM. Embodiments integrate the memory architecture (a 3D memory stack) on the backside of CMOS logic circuits in a die, thereby being called “backside memory.” Accordingly, provided embodiments reduce size/dimensions and enable an efficient process flow while delivering the required operating speeds and memory storage.

Embodiments advantageously employ a high performance (HP) thin film transistor (TFT) architecture to enable fabricating backside memory after metallization starts, or as part of back end of line (BEOL) processes. During BEOL processes, devices such as transistors, capacitors, and resistors, may get connected with a metal (often with Cu or Al) trace/wire on a wafer. BEOL processes may be performed in temperatures of 500 to 600 degrees Celsius, which contrasts with many front end of line (FEOL) processes (such as, some logic fabrication stages), which can reach temperatures of 1000 to 1200 degrees Celsius. The HP TFT channel material (described in more detail below) is selected to be suitable for fabricating the memory stack at the lower BEOL temperatures while still delivering the switching speed requirements of a 3D memory stack in the CIM component. Accordingly, various embodiments fabricate the memory stack in the BEOL processes, after the logic fabrication is completed.

Further, provided embodiments are not reliant upon the communication busses of previous architectures for communication between logic and memory. Instead, provided embodiments implement a technologically improved through silicon via (TSV) technology to connect the logic and the memory in the die. The provided TSVs go from the logic through a silicon substrate to the memory stack on the opposing face of the die. Advantageously, provided embodiments reduce the path length between memory and logic to a few microns, far less than the current path length which, as mentioned, can be in the mm to cm range.

The provided embodiments can be detected in various ways. Utilizing a scanning electron microscope or transmission electron microscope (TEM) can identify the backside memory and/or the HP TFT channel material in the channel of a TFT. A more detailed description of the embodiments follows a terminology section.

### Terminology

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Terms or values modified by the word “substantially” include arrangements, orientations, spacings, or positions that vary by plus or minus 20% (inclusive) from the meaning of the unmodified term or value. Terms or values modified by the word “about” include values inclusive of 10% less than the term or value to inclusive of 10% greater than the term or value.

Nanoribbon (NR) architecture refers to available technology that fabricates transistors by stacking multiple ribbons (often of silicon or silicon-germanium) in a self-aligning and substantially parallel orientation and fabricates the gate material “all around” individual ribbons.

As used herein, the terms “processor unit”, “processing unit” or “processor” may refer to any device or portion of a device that processes electronic data from registers and/or memory to transform that electronic data into other electronic data that may be stored in registers and/or memory. A processor unit may be a system-on-a-chip (SOC), and/or include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

As used herein, the term “electronic component” can refer to an active electronic circuit (e.g., a processing unit, a memory, a storage device, a field effect transistor (FET)) or a passive electronic component (e.g., resistor, inductor, capacitor).

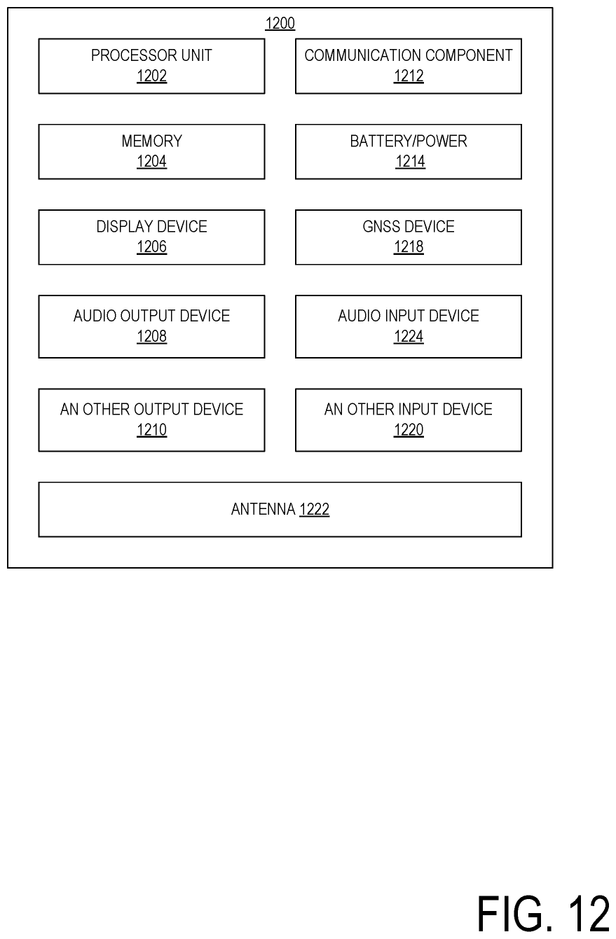

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (sec, e.g., FIG. 12 discussion for processor unit 1202 definition), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS) component; the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

### Description of Embodiments

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

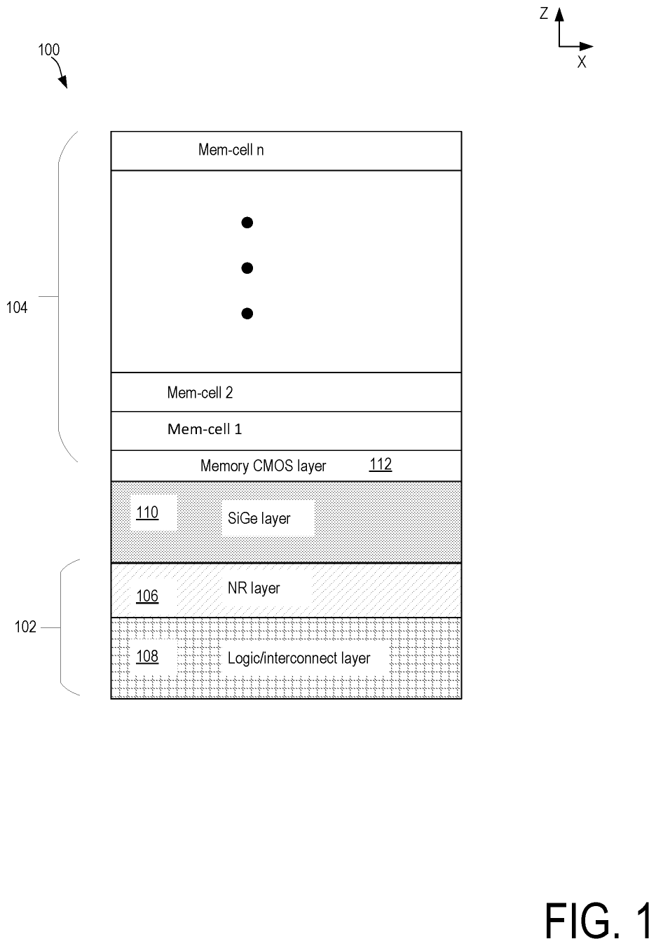

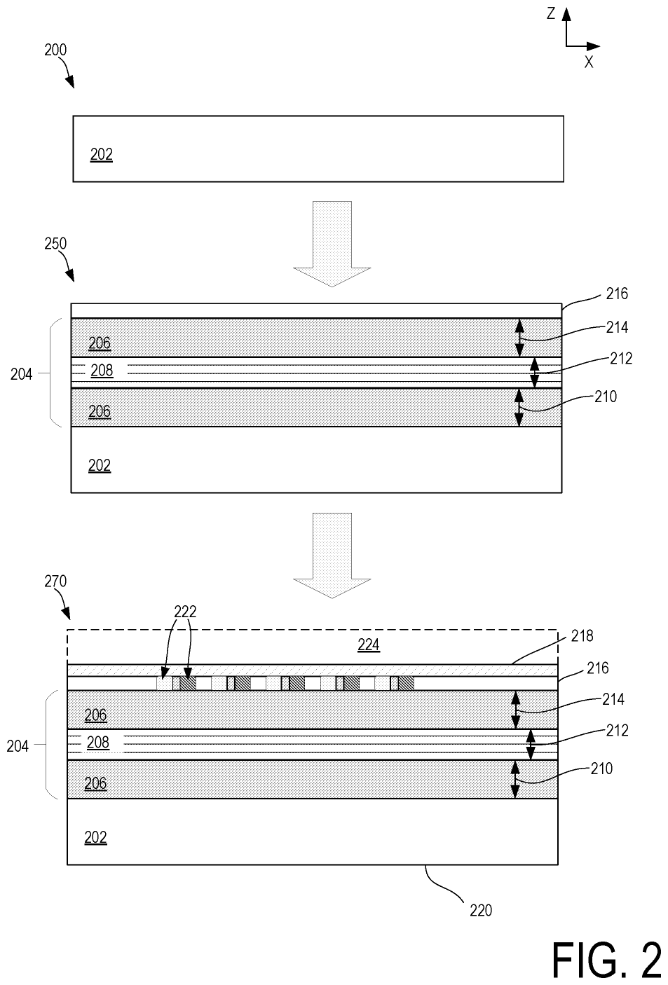

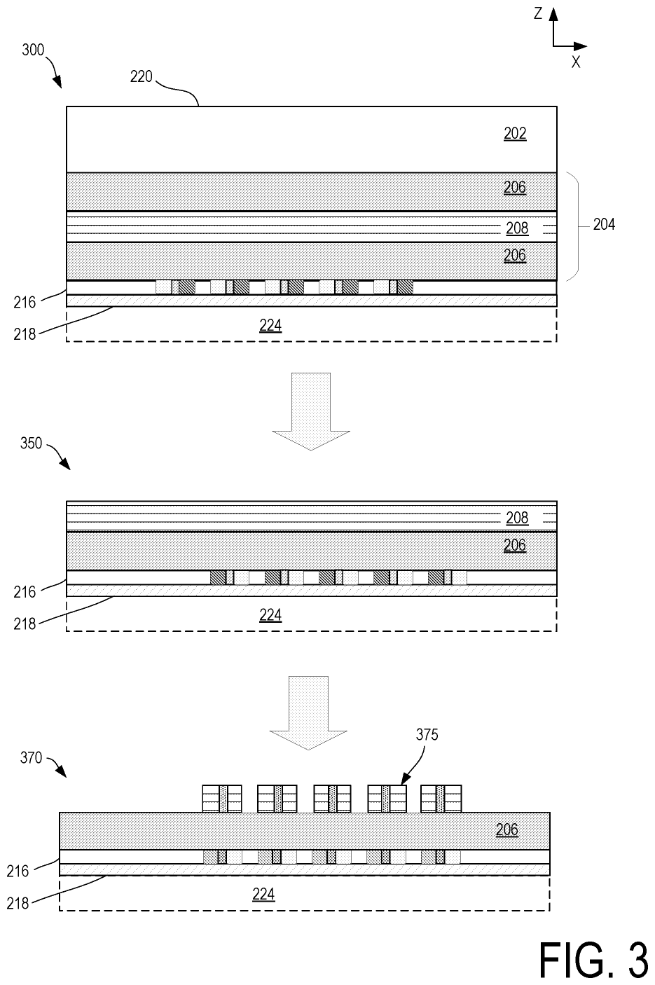

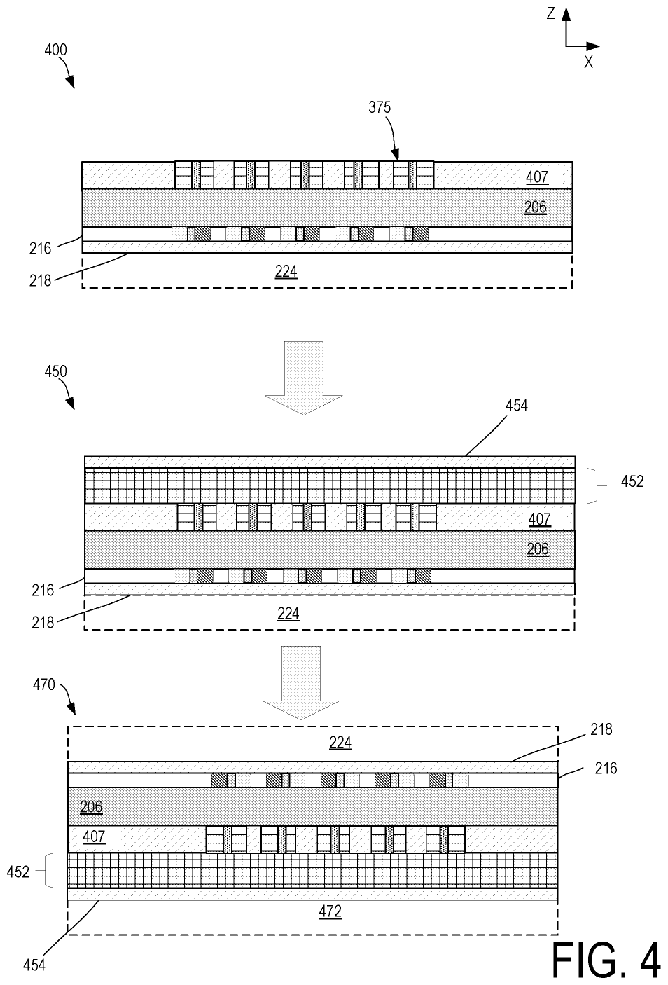

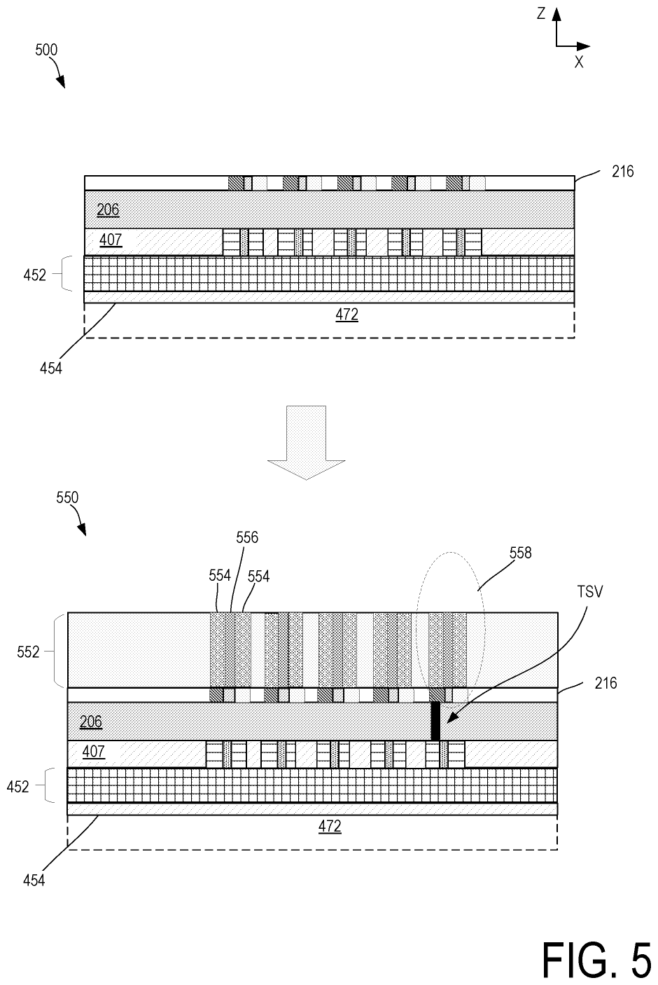

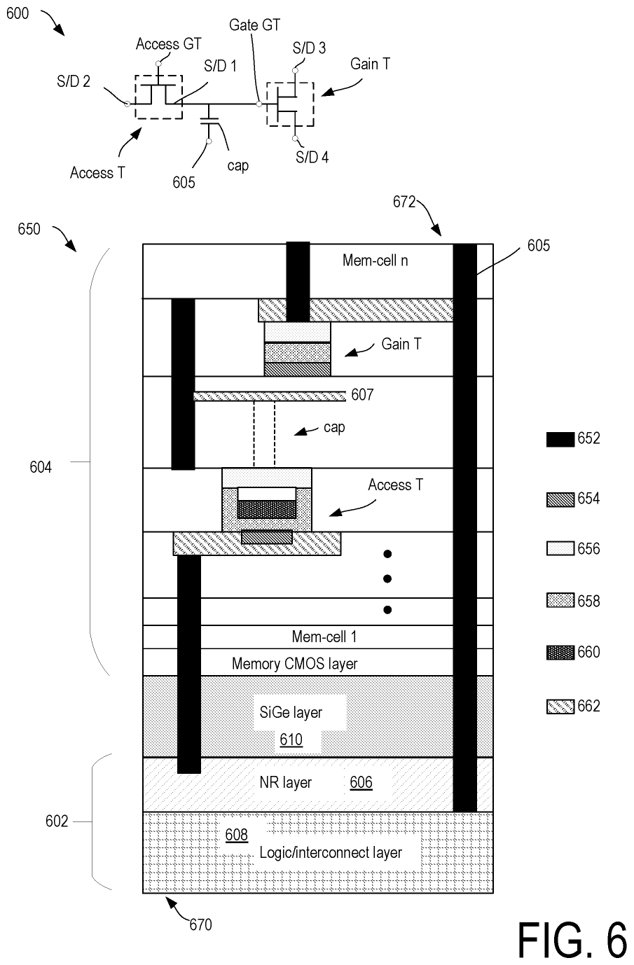

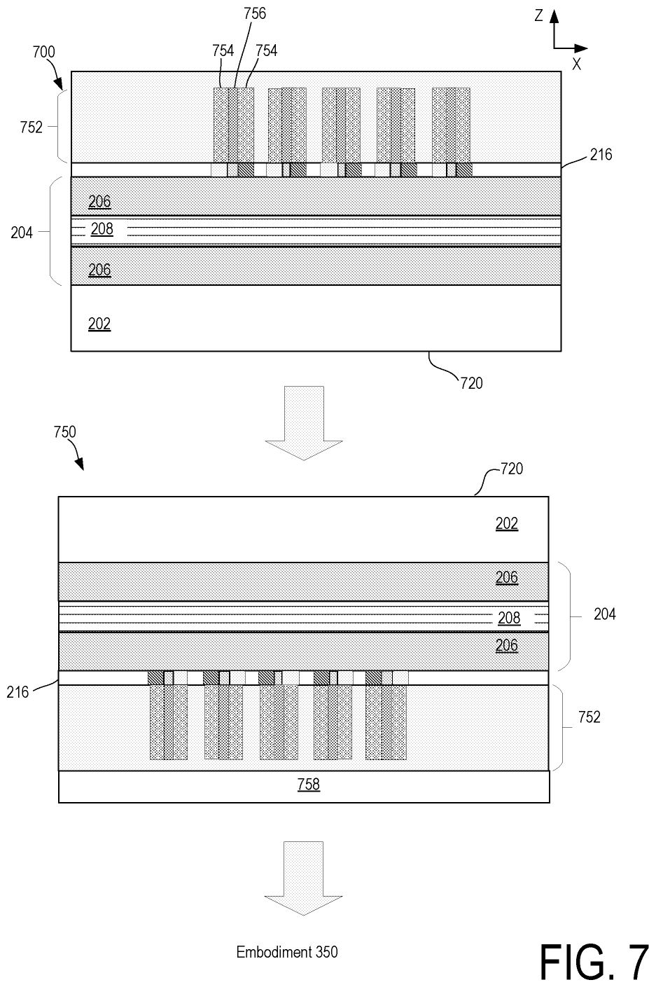

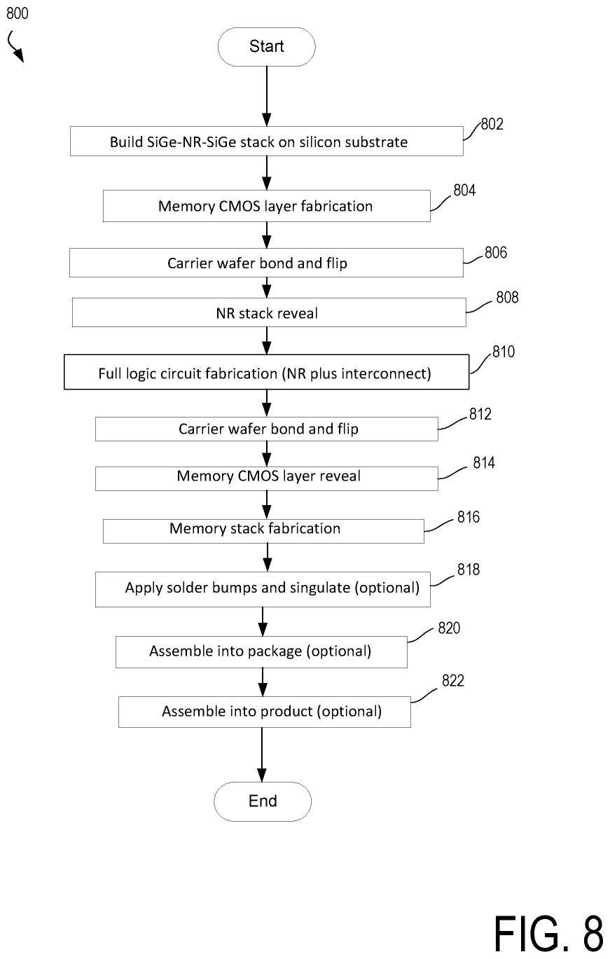

This detailed description is organized as follows. FIG. 1 is a simplified cross-sectional image 100 of some of the fabrication layers in a wafer, for introduction of concepts. FIGS. 2-5 are simplified cross-sectional views of embodiments in various stages of fabrication, in accordance with various embodiments. FIG. 6 is a revisit of FIG. 1, with additional detail for discussing an exemplary memory cell in the BEOL layers. FIG. 7 illustrates a variation in fabrication, in accordance with various embodiments. The discussion of FIGS. 1-7 reference FIG. 8, an exemplary process flow 800 for fabrication of embodiments defined herein. Subsequent figures provide context and potential use scenarios for embodiments described herein.

Turning now to FIG. 1, a simplified wafer profile cross sectional image 100 shows FEOL 102 processing layers located toward the bottom and BEOL 104 layers located toward the top of the image 100. The FEOL 102 layers include a nano-ribbon layer (NR 106) and a logic/interconnect layer 108. A silicon germanium (SiGe) layer 110 separates the FEOL from the BEOL 104. The BEOL 104 comprises a plurality of memory cell layers, denoted Mem-cell1, Mem-cell2, etc., to Mem-cell n, with Mem cell n being closest to an upper surface (at the top of the image 100). The memory cell layers are separated by a dielectric material that may be referred to as BEOL substrate material to distinguish it from other dielectric materials in the wafer profile. In various embodiments, a memory CMOS layer 112 is located in between the SiGe layer 110 and the first memory cell layer Mem-cell 1. As mentioned above, present embodiments build the memory stack in the BEOL 104 layers and employ TSVs through the SiGe layer 110 to facilitate logic connections in FEOL 102 layers with the memory stack in the BEOL 104. These concepts are developed in more detail below.

Embodiment 200 illustrates starting a process flow using a wafer comprising a silicon substrate 202 material. In various embodiments the silicon substrate 202 material comprises silicon or alternative materials, which may or may not be combined with silicon, that include, but are not limited to, germanium, indium antimonide, lead telluride, indium arsenide, indium phosphide, gallium arsenide, or gallium antimonide.

Embodiment 250 shows a SiGe-NR-SiGe stack 204 built or layered on the silicon substrate 202 (at 802). The SiGe-NR-SiGe stack 204 may comprise a SiGe layer 206, located on and adjacent to the silicon substrate 202, having thickness 210, followed by a nanoribbon (NR) layer 208 having thickness 212, followed by another SiGe layer 206, having thickness 214. In various embodiments, the NR layer 208 is sandwiched by, and adjacent to, two different SiGe layers 206. In various embodiments, a first SiGe layer 206 includes a crystalline silicon; thickness 210 and a second SiGe layer 206 includes a crystalline silicon of thickness 214; thickness 210 and thickness 214 may each be about 100 nanometers (nm).

In various embodiments, the NR layer 208 may include a stack of about 7 to about 8 layers of silicon in a thickness 212 of about 70 to about 80 nm. The NR layer 208 is sometimes referred to as a superlattice. Above the uppermost SiGe layer 206, there may be a layer of silicon 216 that is utilized for channel material for fabrication of a base CMOS memory layer in embodiment 270.

At 804 the layer of silicon 216 is fabricated and transformed into a base memory CMOS layer (shortened to CMOS layer 216), as illustrated in embodiment 270. The CMOS layer 216 may be a CMOS logic base that is in a range of about 5 microns to about 10 microns thick and may include variously placed source/drain regions 222. A bonding-compatible oxide layer 218 may be overlaid on the layer of silicon 216. At 806, a carrier wafer 224 may be bonded to oxide layer 218, and the wafer can then be flipped (or, inverted), as shown in embodiment 300. Note that surface 220 is on the top of the figure in embodiment 300 and carrier wafer 224 is on the bottom of the figure in embodiment 300.

At 808, the NR layer is revealed. In various embodiments, NR reveal may include a mechanical polish/grind followed by a wet etch. The SiGe layer 206 may act as a grind/polish stop with an acceptable non-uniformity for the fabrication that follows. In various embodiments, a chemical etch may be performed for removal of a top layer of SiGe. Although not indicated for simplicity in the figure, in various embodiments, there may be about 50 nm to about 100 nm of SiGe layer 206 left on top of the NR layer 208 after the grind at 808.

Once the NR layer 208 is revealed (embodiment 350), at 810, full logic circuit fabrication is performed. Full logic circuit fabrication includes, first, using lithography and etching procedures to transform the NR layer 208 into NR towers 375 or pillars (embodiment 370) that become the heart of transistors that embody the “logic” or “logic component” (i.e., a logic integrated circuit component) for the CIM component. Individual transistors can be fabricated at 810 with source/drain (S/D) contacts and transistors can then be isolated from each other with a dielectric material, creating NR transistor layer 407 embodiment 400. Once the NR transistor layer 407 has been completed, interconnect layers 452 can be fabricated to route signals between different transistors in the NR towers 375. Upon completion, a logic component has an upper surface that is adjacent to a lower surface of the SiGe layer 610, and a lower surface that may also be the lower surface 670 of the CIM component. Thus, the FEOL processing (at 810) 6 has been completed.

Another bonding-compatible oxide layer 454 may be overlaid on the interconnect layer as shown in embodiment 450. Another carrier wafer 472 may be implemented at 812, bonded to the surface of oxide layer 454, and the wafer is again flipped, as illustrated with embodiment 470.

In embodiment 500, carrier wafer 224 is removed and the oxide layer 218 is removed, by either wet etch or a grind process, to reveal (at 814) the CMOS layer 216 fabricated on the SiGe layer (at 804). Once this task has been performed, the embodiment 500 cannot be subjected to the high temperatures of FEOL processing anymore.

Backside memory stack fabrication is performed in BEOL processing at 816. In the simplified illustration of embodiment 550, a memory stack 552 is built directly on the CMOS layer 216. The memory stack comprises multiple memory cells located in as BEOL substrate material, the memory cells comprising channel material 556. The memory cell may further be described as having multiple S/D regions 554. Embodiments may include a plurality of TSVs extending from the memory stack 552 through the SiGe 206 to the NR transistor layer 407 and connect with individual traces in interconnect layer 452, although only one is shown, for simplicity. The TSV comprises conductive material and communicatively couples the logic component to the memory cell or other components in the BEOL layers 604.

In various embodiments, the channel material 556 used in the memory cell includes one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, and black phosphorus.

In various embodiments, the channel material 556 is the above-referenced HP TFT material. The dashed oval 558 indicates a region in which the HP TFT can be found, for the purpose of reviewing a TEM image. In various embodiments, the HP TFT material may be deposited using atomic layer deposition (ALD), chemical vapor deposition (CVD), or physical vapor deposition (PVD), or other suitable technique. In various embodiments, the HP TFT material is a versatile material that can be grown on any suitable substrate such as a crystalline or a non-crystalline structure (e.g., a dielectric material, such as silicon oxide, silicon nitride, metal oxide, silicon oxynitride, etc.) or other varactor material (e.g., an anode or dielectric material). Thus, the HP TFT material may be grown independent of a semiconductor substrate in particular embodiments.

The HP TFT material may comprise any suitable semiconductor material exhibiting a high mobility and a relatively wide bandgap voltage. In various embodiments, the mobility of the HP TFT material is higher than 20 cm2/(V·s). In other embodiments, the mobility of the HP TFT material is higher than 50 cm2/(V·s). In some embodiments, the mobility of the HP TFT material is between 5 cm2/(V·s) and 700 cm2/(V·s). In various embodiments, the bandgap voltage of the HP TFT material is higher than the bandgap voltage of silicon (e.g., 1.14 eV @302K). In some examples, the bandgap voltage of the HP TFT material is higher than 1.2 eV @302K. In particular embodiments, the bandgap voltage of the HP TFT material is higher than the bandgap voltage of silicon but lower than 6.5 eV @300K, including all values and ranges therein. In various embodiments, the bandgap voltage of the HP TFT material is higher than the bandgap voltage of a substrate upon which a transistor comprising the HP TFT material is formed.

In various embodiments, the HP TFT material comprises an oxide (e.g., a metal oxide), such as indium gallium zinc oxide (IGZO), indium tin oxide (ITO), indium zinc oxide (IZO), zinc oxide, indium oxide, gallium oxide, copper oxide, tin oxide, or other suitable oxide. In some oxides, a material with insulating properties may be introduced into the oxide to increase the bandgap voltage. For example, doping indium oxide with hafnium oxide (which exhibits insulating properties) will result in a composite HP TFT material with a wider bandgap than the indium oxide. Similarly, indium oxide or zinc oxide may be doped with gallium oxide (which exhibits insulating properties) to produce a composite HP TFT material with a wider bandgap voltage.

In some embodiments, the HP TFT material comprises a nitride (e.g., a metal nitride), such as zinc nitride, indium nitride, gallium nitride, copper nitride, aluminum nitride, or other suitable nitride. In some nitrides, a material with insulating properties may be introduced into the nitride to increase the bandgap voltage. For example, aluminum nitride (which exhibits insulating properties) may be added to indium nitride, zinc nitride, or gallium nitride to produce a composite HP TFT material with an increased bandgap voltage.

In some embodiments, the HP TFT material comprises a chalcogenide, such as a selenide or sulfide of molybdenum, tungsten, indium, gallium, zinc, copper, hafnium, aluminum, or germanium.

In some embodiments, the HP TFT material comprises any other suitable material, such as black phosphorous, graphene, carbon nanotubes, polysilicon, poly germanium, poly III-V (gallium arsenide, etc.). While some of these materials have a narrower bandgap voltage than silicon in certain compositions, the concentration of certain elements (e.g., gallium) may be increased to improve the bandgap voltage of the resulting HP TFT material.

As those with skill will appreciate, the backside memory stack 552 may be implemented using a variety of different memory cell architectures. In a non-limiting example, a memory cell 600 is a two-transistor thin film transistor (TFT) component including an access thin-film transistor (TFT), an optional capacitor and a gain TFT. Optional capacitor may have one terminal coupled to a plate line 607 for voltage generation. The access TFT and gain TFT each comprise the HP TFT channel material.

Embodiment 650 provides a non-limiting example of an implementation of the memory cell 600 in the wafer layers of image 100, or CIM component. The BEOL layers 604 are located on a SiGe layer 610, which is located on/above the FEOL layers 602. The wafer (or individual CIM component) is oriented with the logic on the bottom in the figure, the bottom surface 670 of the CIM is indicated, and an upper surface 672 of the CIM is indicated. The gain TFT and the access TFT are substantially stacked (vertically), and they are above the base CMOS memory layer, which is directly on the SiGe layer 610.

The gain TFT is depicted in an upper layer of the BEOL 604, and the access TFT in a layer below the gain TFT, but still in the BEOL 604. The optional capacitor is in a layer of BEOL 604 between the gain TFT and the access TFT. Horizontally routed metal interconnects 662 and vertically routed metal traces 652 may include one or more TSVs, and TSVs may extend from the NR layer 606 or interconnect layer 608 to the upper surface, as illustrated with TSV 605. Source material 656 is distinguished from drain material 654 and from gate material 660. The channel material 658 may comprise the HP TFT channel material described above.

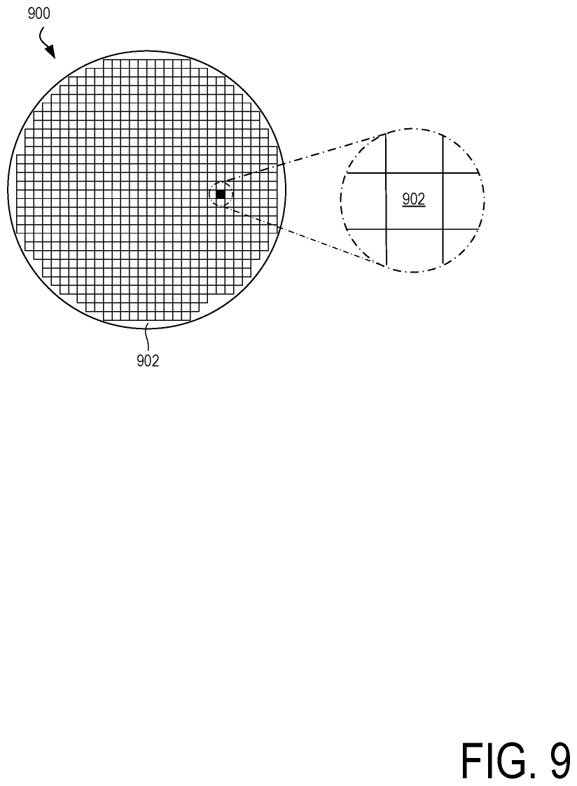

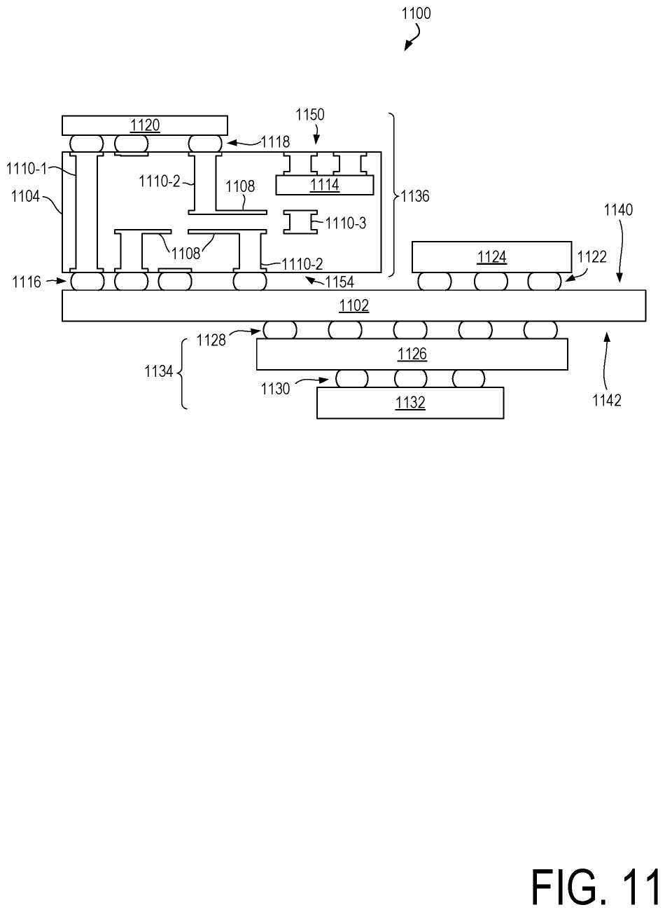

In various embodiments, the upper surface 672 is then patterned with solder bumps (at 818, not shown). A wafer comprising CIM components may then be singulated or cut apart and assembled into a package assembly at 820 (e.g., see FIG. 9). A package assembly may comprise a printed circuit board attached to solder bumps (e.g., see FIG. 11). The package assembly may further be assembled with a heat spreader component attached above the upper surface of the BEOL substrate. In various embodiments, an integrated circuit component may be attached to the printed circuit board. In various embodiments, a thermal interface material (TIM) may be located between a heat spreader component and the upper surface of the BEOL substrate.

A package assembly comprising the above CIM architecture may further be assembled into a device or product (at 822); the device or product may further include a power supply, a communication system/component, or any of a variety of other components, as illustrated in FIG. 12.

In the non-limiting example of embodiment 650, a first source/drain (S/D 1) electrode of the access TFT is coupled to a gate electrode of the gain TFT (Gate GT), the access TFT is in a first layer over a substrate, and the gain TFT is in a second layer over the substrate, the first layer being between the substrate and the second layer.

In various embodiments, the access TFT includes a channel material and a second S/D electrode (S/D 2), the first S/D electrode of the access TFT is over the channel material of the access TFT, and the channel material of the access TFT is over the second S/D electrode of the access TFT.

Further, in various embodiments, the gain TFT includes a channel material, a first S/D electrode (S/D 3), and a second S/D electrode (S/D 4). The gate electrode of the gain TFT is between the substrate (BEOL 604 substrate material) and the channel material of the gain TFT. and the channel material of the gain TFT is between the gate electrode of the gain TFT and the first S/D electrode of the gain TFT and also between the gate electrode of the gain TFT and the second S/D electrode of the gain TFT.

In another variation, the stages of fabrication may alter slightly from FIG. 8, as illustrated in FIG. 7. In embodiment 700, after building the SiGe-NR-SiGe stack 204 on the silicon substrate 202, the base memory CMOS layer 216 is fabricated on the uppermost SiGe layer 206, as shown. From there, memory stack 752 fabrication can be performed as described above, creating stacks of source/drain regions 754 and channels 756. A carrier 758 can be bonded to the memory stack and the wafer flipped, as illustrated in embodiment 750 (note the changed position of surface 720). From embodiment 750, the fabrication can move to embodiment 350, in which the silicon substrate 202 and layer of SiGe 206 are removed, also as described above. The variation shown in FIG. 7 may be less costly, having less fabrication tasks. A drawback of the variation of FIG. 7 is that it does not take advantage of the back end (BEOL) compatibility of the HP TFT channel material.

Thus, architectures and methods for computation in memory (CIM) with backside memory using high performance (HP) thin film transistor (TFT) material have been described. An embodiment of the provided architecture may be referred to as an integrated circuit component, be it packaged or unpackaged. The following description illustrates context for usage and application of provided embodiments.

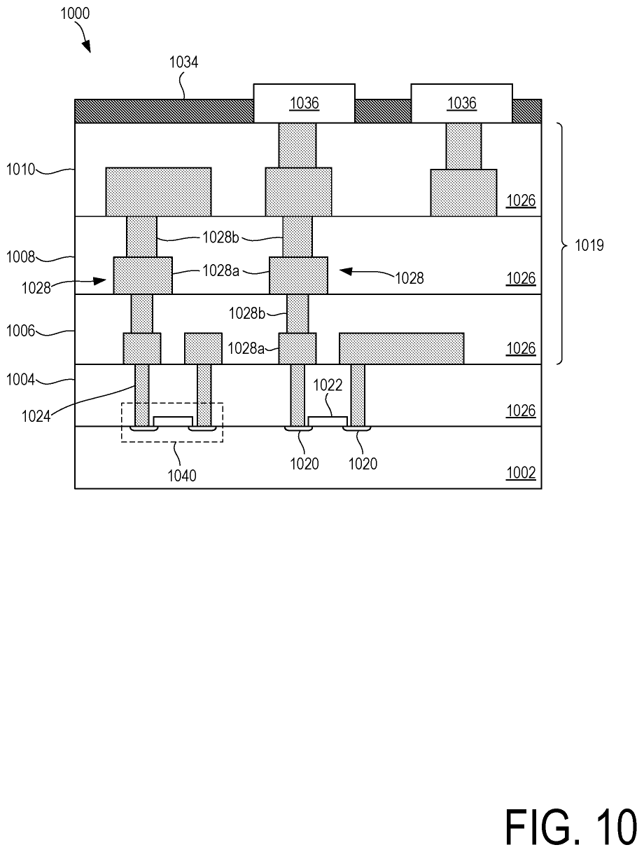

FIG. 9 is a top view of a wafer 900 and dies 902 that may embody integrated circuit components, in accordance with any of the embodiments disclosed herein. The wafer 900 may be composed of semiconductor material and may include one or more die 902 having integrated circuit structures formed on a surface of the wafer 900. The individual circuit structures on the die 902 may embody/implement an integrated circuit product or semiconductor product. After the fabrication of the semiconductor product is complete, the wafer 900 may undergo a singulation process in which the die 902 are separated from one another to provide discrete “chips” of the integrated circuit product. Respective die 902 may be any of the die disclosed herein. The die 902 may include one or more transistors (e.g., transistors referred to above, and/or some of the transistors 1040 of FIG. 10, discussed below), supporting circuitry to route electrical signals to the transistors, passive components (e.g., signal traces, resistors, capacitors, or inductors), and/or any other integrated circuit components.

In some embodiments, in addition to or in conjunction with the above description, the wafer 900 or the die 902 may include a memory device (c.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1202 of FIG. 12) or other logic that is configured to store information in the memory devices or execute instructions stored in the memory array. Various ones of the microelectronics assemblies 1100 disclosed herein may be manufactured using a die-to-wafer assembly technique in which some dies are attached to a wafer 900 that include others of the dies 902, and the wafer 900 is subsequently singulated.

FIG. 10 is a cross-sectional side view of an integrated circuit component 1000 implemented on a die that may be included in any of the that may embody integrated circuit components, in accordance with any of the embodiments disclosed herein. One or more of the integrated circuit components 1000 may be included in one or more dies 902 (FIG. 9). The integrated circuit component 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit component 1000 may be used. The die substrate 1002 may be part of a singulated die (e.g., the dies 902 of FIG. 9) or a wafer (e.g., the wafer 900 of FIG. 9).

The integrated circuit component 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Continuing with FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit component 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit components having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines that are interconnect structures 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit component 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit component 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit component 1000 with another component (e.g., a printed circuit board). The integrated circuit component 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit component 1000 is double-sided (e.g., 902, FIG. 9), the integrated circuit component 1000 may include another metallization stack (not shown) on the opposite side of the device layer(s) 1004. This metallization stack may include multiple interconnect layers as discussed above with reference to the interconnect layers 1006-1010, to provide conductive pathways (c.g., including conductive lines and vias) between the device layer(s) 1004 and additional conductive contacts (not shown) on the opposite side of the integrated circuit component 1000 from the conductive contacts 1036.

In other embodiments in which the integrated circuit component 1000 is a double-sided, the integrated circuit component 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit component 1000 from the conductive contacts 1036. In some embodiments, TSVs extending through the substrate can be used for routing power and ground signals from conductive contacts on the opposite side of the integrated circuit component 1000 from the conductive contacts 1036 to the transistors 1040 and any other components integrated into the die of the integrated circuit component 1000, and the metallization stack 1019 can be used to route I/O signals from the conductive contacts 1036 to transistors 1040 and any other components integrated into the die of the integrated circuit component 1000.

Multiple integrated circuit components 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 11 is a cross-sectional side view of a “package assembly” or microelectronics assembly 1100 that may include an apparatus or structure disclosed herein. The microelectronics assembly 1100 includes a number of components disposed on a circuit board 1102 (which may be a motherboard, system board, mainboard, etc.). The microelectronics assembly 1100 includes components disposed on a first face 1140 of the circuit board 1102 and an opposing second face 1142 of the circuit board 1102; generally, components may be disposed on one or both faces 1140 and 1142.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. In some embodiments the circuit board 1102 may be, for example PCB. The microelectronics assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 902 of FIG. 9, the integrated circuit component 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers. sensors, electrostatic discharge (ESD) devices, and memory devices.

In embodiments where the integrated circuit component 1120 comprises multiple integrated circuit die, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11. the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The microelectronics assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The microelectronics assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include an apparatus and/or structure disclosed herein. For example, any suitable ones of the components of the electrical device 1200 may include one or more of the apparatus (e.g., 100, 130, 140), structures (e.g., 208, 214, 216), microelectronic assemblies 1100, integrated circuit components, or integrated circuit dies 902 disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die. In some embodiments, some or all of the components included in the electrical device 1200 may be enclosed in a housing 1226.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202, as defined herein. The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (cDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such speakers, headsets, or carbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include another output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include another input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an Ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” can mean any combination of the listed terms. For example, the phrase “at least one of A, B and C” can mean A; B; C; A and B; A and C; B and C; or A, B, and C. Similarly, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and sub-combinations with one another. The disclosed methods, apparatuses, and systems are not limited to any specific aspect or feature or combination thereof, nor do the disclosed embodiments require that any one or more specific advantages be present, or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following Examples pertain to additional embodiments of technologies disclosed herein.

Example 1 is an apparatus, comprising: a memory cell, comprising a first thin-film transistor (TFT) and a second TFT; a channel material; the channel material located in the first TFT and in the second TFT; and the channel material characterized by a bandgap voltage above 1.14 electron volts (eV) at 302 degrees Kelvin.

Example 2 includes the subject matter of Example 1, wherein the bandgap voltage is above 1.2 eV at 302 degrees Kelvin.

Example 3 includes the subject matter of Example 1, wherein the channel material is characterized by a mobility that is higher than 20 centimeters squared per volt second (cm2/(V·s)).

Example 4 includes the subject matter of any one of Examples 1-3, wherein the mobility is higher than 50 cm2/(V·s).

Example 5 includes the subject matter of any one of Examples 1-3, wherein the mobility is between 100 cm2/(V·s) and 700 cm2/(V·s).

Example 6 includes the subject matter of any one of Examples 1-5, wherein the channel material includes one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, and black phosphorus.

Example 7 includes the subject matter of any one of Examples 1-5, wherein the channel material includes: one or more of indium gallium zinc oxide (IGZO), indium tin oxide (ITO), indium zinc oxide (IZO), zinc oxide, indium oxide, gallium oxide, copper oxide, tin oxide, or other suitable oxide; and a material with insulating properties.

Example 8 includes the subject matter of any one of Examples 1-7, further comprising: a back end of line (BEOL) substrate having an upper surface and a lower surface, the upper surface of the BEOL substrate including solder bumps; the memory cell located between the upper surface and the lower surface of the BEOL substrate; a logic component having a top surface and a bottom surface; and a silicon-germanium (SiGe) layer, the SiGe layer located between the top surface of the logic component and the lower surface of the BEOL substrate.

Example 9 includes the subject matter of Example 8, further comprising a through silicon via (TSV) that communicatively couples the logic component to the memory cell.

Example 10 includes the subject matter of Example 8 or Example 9, wherein the logic component comprises nanoribbon architecture.

Example 11 is a package assembly comprising the subject matter of Example 8 or Example 9, and further comprising a printed circuit board attached to the solder bumps.

Example 12 includes the package assembly of Example 11, further comprising a heat spreader component attached above the upper surface of the BEOL substrate.

Example 13 includes the package assembly of Example 11 or Example 12, further comprising an integrated circuit component attached to the printed circuit board.

Example 14 includes the package assembly of Example 12, further comprising a thermal interface material (TIM), located between the heat spreader component and the upper surface of the BEOL substrate.

Example 15 is a device comprising the subject matter of any one of Examples 1-14, and further comprising one or more of a power supply and a communication component.

Example 16 is a system comprising: a back end of line (BEOL) substrate having an upper surface and a lower surface, the upper surface of the BEOL substrate including solder bumps; a memory cell located between the upper surface and the lower surface of the BEOL substrate, the memory cell comprising a first thin-film transistor (TFT) and a second TFT, the first TFT and the second TFT comprising a channel material, the channel material characterized by a bandgap voltage above 1.14 electron volts (eV) at 302 degrees Kelvin; a logic component having a top surface and a bottom surface; and a silicon-germanium (SiGe) layer, the SiGe layer located between the top surface of the logic component and the lower surface of the BEOL substrate.

Example 17 includes the subject matter of Example 16, wherein the bandgap voltage is above 1.2 eV at 302 degrees Kelvin.

Example 18 includes the subject matter of Example 16 or Example 17, wherein the channel material is characterized by a mobility that is higher than 20 centimeters squared per volt second (cm2/(V·s)).

Example 19 is a method, comprising: building a silicon-germanium (SiGe)-nanoribbon (NR) layer-SiGe stack on a silicon substrate; creating a complementary metal oxide semiconductor (CMOS) layer on an upper surface of the SiGe stack; inverting the CMOS layer to bring the silicon substrate to a top, using a first carrier wafer to the CMOS layer; exposing the NR layer; fabricating a logic component using the NR layer and interconnect layers; inverting the logic component to a bottom, using a second carrier wafer; exposing the CMOS layer; and building a backside memory stack on the CMOS layer using back end of line (BEOL) processing.

Example 20 includes the subject matter of Example 19, further comprising: attaching solder bumps to an upper surface of the backside memory stack.

What is claimed is:

1. An apparatus, comprising:
a memory cell comprising a first thin-film transistor (TFT) and a second TFT;
a channel material;
the channel material located in the first TFT and in the second TFT; and
the channel material includes one or more of indium gallium zinc oxide (IGZO), indium tin oxide (ITO), indium zinc oxide (IZO), zinc oxide, indium oxide, gallium oxide, copper oxide, tin oxide, or other suitable oxide, and a material with insulating properties.

2. The apparatus of claim 1, wherein the channel material is characterized by a bandgap voltage above 1.2 eV at 302 degrees Kelvin.

3. The apparatus of claim 1, wherein the channel material is characterized by a mobility that is higher than 20 centimeters squared per volt second (cm2/(V·s)).

4. The apparatus of claim 3, wherein the mobility is higher than 50 cm2/(V·s).

5. The apparatus of claim 3, wherein the mobility is between 100 cm2/(V·s) and 700 cm2/(V·s).

6. The apparatus of claim 1, wherein the channel material includes one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, and black phosphorus.

7. The apparatus of claim 1, wherein the channel material is characterized by a bandgap voltage above 1.14 electron volts (eV) at 302 degrees Kelvin.

8. The apparatus of claim 1, further comprising:
a back end of line (BEOL) substrate having an upper surface and a lower surface, the upper surface of the BEOL substrate including solder bumps;
the memory cell located between the upper surface and the lower surface of the BEOL substrate;
a logic component having a top surface and a bottom surface; and
a silicon-germanium (SiGe) layer, the SiGe layer located between the top surface of the logic component and the lower surface of the BEOL substrate.

9. The apparatus of claim 8, further comprising a through silicon via (TSV) that communicatively couples the logic component to the memory cell.

10. The apparatus of claim 8, wherein the logic component comprises nanoribbon architecture.

11. A package assembly comprising the apparatus of claim 9, and further comprising a printed circuit board attached to the solder bumps.

12. The package assembly of claim 11, further comprising a heat spreader component attached above the upper surface of the BEOL substrate.

13. The package assembly of claim 11, further comprising an integrated circuit component attached to the printed circuit board.

14. The package assembly of claim 12, further comprising a thermal interface material (TIM), located between the heat spreader component and the upper surface of the BEOL substrate.

15. A device comprising the apparatus of claim 8, and further comprising one or more of a power supply and a communication system.

16. A system comprising:
a back end of line (BEOL) substrate having an upper surface and a lower surface, the upper surface of the BEOL substrate including solder bumps;
a memory cell located between the upper surface and the lower surface of the BEOL substrate, the memory cell comprising a first thin-film transistor (TFT) and a second TFT, the first TFT and the second TFT comprising a channel material, the channel material including one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, indium gallium zinc oxide (IGZO), indium telluride, molybdenite, molybdenum diselenide, tungsten diselenide, tungsten disulfide, and black phosphorus;
a logic component having a top surface and a bottom surface; and
a silicon-germanium (SiGe) layer, the SiGe layer located between the top surface of the logic component and the lower surface of the BEOL substrate.

17. The system of claim 16, wherein the channel material is characterized by a bandgap voltage above 1.14 electron volts (eV) at 302 degrees Kelvin.

18. The system of claim 16, wherein the channel material is characterized by a mobility that is higher than 20 centimeters squared per volt second (cm2/(V·s)).

19. A method, comprising:
building a silicon-germanium (SiGe)-nanoribbon (NR) layer-SiGe stack on a silicon substrate;
creating a complementary metal oxide semiconductor (CMOS) layer on an upper surface of the SiGe stack;
inverting the CMOS layer to bring the silicon substrate to a top, using a first carrier wafer to the CMOS layer;
exposing the NR layer;
fabricating a logic component using the NR layer and interconnect layers;
inverting the logic component to a bottom, using a second carrier wafer;
exposing the CMOS layer; and
building a backside memory stack on the CMOS layer using back end of line (BEOL) processing.

20. The method of claim 19, further comprising attaching solder bumps to an upper surface of the backside memory stack.
